(19) United States
(12) Patent Application Publication
(10) Pub. No.: US 2017/0033272 A1
(43) Pub. Date: Feb. 2, 2017

(54) METHOD TO MAKE A FLEXIBLE THERMOELECTRIC GENERATOR DEVICE AND RELATED DEVICES

(71) Applicant: STMICROELECTRONICS S.r.l., Agrate Brianza (IT)

(72) Inventors: Immacolata PEDACI, Quarto (IT); Angela CIMMINO, Caserta (IT); Valeria CASUSCELLI, Napoli (IT); Giampiero PEPE, San Nazzaro (IT)

(21) Appl. No.: 14/814,660

(22) Filed: Jul. 31, 2015

(51) Int. Cl. H01L 35/34; H01L 35/32

(52) U.S. Cl. CPC H01L 35/34; H01L 35/32

(57) ABSTRACT

A method is for making a thermoelectric generator device. The method may include forming bottom contacts on a first substrate, and forming a polymer layer over the first substrate with recesses therein, the recesses being over the bottom contacts. The method may include forming a semiconductor material fluid in the recesses of the polymer layer to define thermoelectric couples coupled to the bottom contacts, forming top contacts adjacent a second substrate, and positioning the second substrate so that the top contacts are coupled to the thermoelectric couples.

### TECHNICAL FIELD

The present disclosure relates to the field of electronic devices, and, more particularly, to a method for making a thermoelectric generator device and related devices.

### BACKGROUND

Integrated circuits (ICs) typically comprise a large number of active devices, for example, transistors. Indeed, it is not uncommon for the typical integrated circuit to have several million active devices. As the density of the integrated circuit has increased, thermal power dissipation, the result of the operation of the integrated circuit, has increased. Typically, the integrated circuit may be paired with a cooling device to compensate for this thermal heat dissipation, for example, a fan and heat sink may be attached to the integrated circuit to remove the heat from the integrated circuit. Nevertheless, this energy is ultimately wasted.

An approach to this issue is the thermoelectric device. The thermoelectric device converts a temperature differential into an electric potential. In some applications, the thermoelectric device is used as an energy generation device where there is an existing thermal gradient. In these applications, the existing thermal gradient is used to power a host device. In other applications, the thermoelectric device is powered to create a thermal gradient, i.e. an active heat dissipater.

### SUMMARY

Generally speaking, a method for making a thermoelectric generator device may include forming a plurality of bottom contacts on a first substrate, and forming a polymer layer over the first substrate with a plurality of recesses therein. The plurality of recesses may be over the plurality of bottom contacts. The method may include forming at least one semiconductor material fluid in the plurality of recesses of the polymer layer to define a plurality of thermoelectric couples coupled to the plurality of bottom contacts, and forming a plurality of top contacts adjacent a second substrate, and positioning the second substrate so that the plurality of top contacts is coupled to the plurality of thermoelectric couples. Advantageously, the thermoelectric generator device may be readily manufactured.

In some embodiments, the method may also include grinding semiconductor material to generate semiconductor powder, and combining the semiconductor powder with a suspension fluid and a solvent to generate the at least one semiconductor material fluid. For example, the suspension fluid may comprise a polymer fluid, and the polymer fluid may comprise a heated thermoplastic material.

More specifically, the forming of the at least one semiconductor material fluid may comprise ink-jet printing the at least one semiconductor material fluid. The method may also include milling the polymer layer to define the plurality of recesses therein. The first substrate and the second substrate, and the polymer layer may each comprise a flexible layer. The at least one semiconductor material fluid may comprise first and second semiconductor material fluids having respective first and second conductivity types. Also, the method may include cooling the plurality of thermoelectric couples to solidify the plurality of thermoelectric couples.

Another aspect is directed to a thermoelectric generator device. The thermoelectric generator device may include a first substrate, a plurality of bottom contacts carried by the first substrate, and a polymer layer over the first substrate and the plurality of bottom contacts, and defining a plurality recesses therein. The thermoelectric generator device may comprise a semiconductor material polymer matrix filling the plurality of recesses in the polymer layer and defining a plurality of thermoelectric couples, a plurality of top contacts coupled to the plurality of thermoelectric couples, and a second substrate carrying the plurality of top contacts.

More specifically, each thermoelectric couple may comprise first and second columns of respective first and second conductivity types. The thermoelectric generator device may comprise first and second terminals coupled to the plurality of bottom contacts. The semiconductor material polymer matrix may comprise a thermoplastic material.

### BRIEF DESCRIPTION OF THE DRAWINGS

FIG. 1 is a flowchart of a method for making a thermoelectric generator device, according to the present disclosure.

FIGS. 2A-2G are schematic side views of steps in the method for making the thermoelectric generator device, according to the present disclosure.

FIG. 3 is a schematic top plan view of the bottom contacts and the first substrate of an embodiment of the thermoelectric generator device, according to the present disclosure.

FIG. 4 is a schematic top plan view of the top contacts and the second substrate of the embodiment of the thermoelectric generator device of FIG. 3.

FIG. 5 is a schematic top plan view of the polymer layer of the embodiment of the thermoelectric generator device of FIG. 3.

FIG. 6 is a schematic perspective view of the thermoelectric generator device of FIG. 3 with the first and second substrates removed.

FIG. 7 is a chart illustrating electric potential in a thermoelectric couple of the embodiment of the thermoelectric generator device of FIG. 3.

FIG. 8 is a chart illustrating thermoelectric efficiency/figure of merit in the thermoelectric couple of the embodiment of the thermoelectric generator device of FIG. 3.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout.

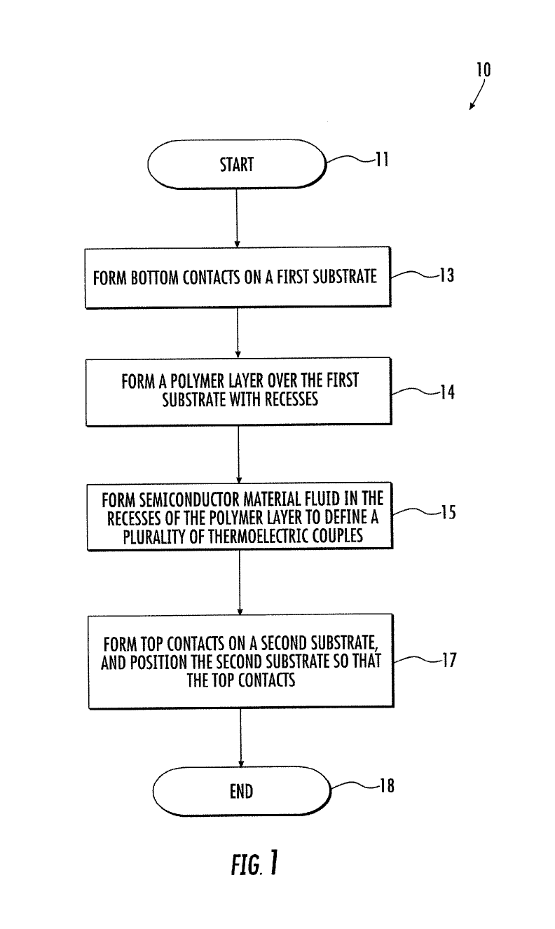

Referring initially to FIGS. 1-5, a thermoelectric generator device 20 according to the present disclosure is now described. Also, with reference to a flowchart 10, a method for making the thermoelectric generator device 20 is also described, beginning at Block 11. The thermoelectric generator device 20 illustratively includes a first substrate 22, a plurality of bottom contacts (e.g. copper, aluminum) 23a-23d carried by the first substrate, and a polymer layer 25 over the first substrate and the plurality of bottom contacts, and defining a plurality recesses 29a-29h. In some embodiments, the polymer layer 25 is flexible and a dielectric. The polymer layer 25 may comprise a polymer material with a low thermal conductivity, such as a polycarbonate with λ=0.12 W/(K*m), polymethyl methacrylate (PMMA) with λ=0.19 W/(K*m), polytetrafluoroethylene (PTFE) with λ=0.25 W/(K*m)

The thermoelectric generator device 20 illustratively includes a semiconductor material polymer matrix filling the plurality of recesses 29a-29h in the polymer layer 25 and defining a plurality of thermoelectric couples 26a-26d, 27a-27d coupled to the plurality of bottom contacts 23a-23d. The thermoelectric generator device 20 illustratively includes a plurality of top contacts (e.g. copper, aluminum) 24a-24e coupled to the plurality of thermoelectric couples 26a-26d, 27a-27d, and a second substrate 21 carrying the plurality of top contacts.

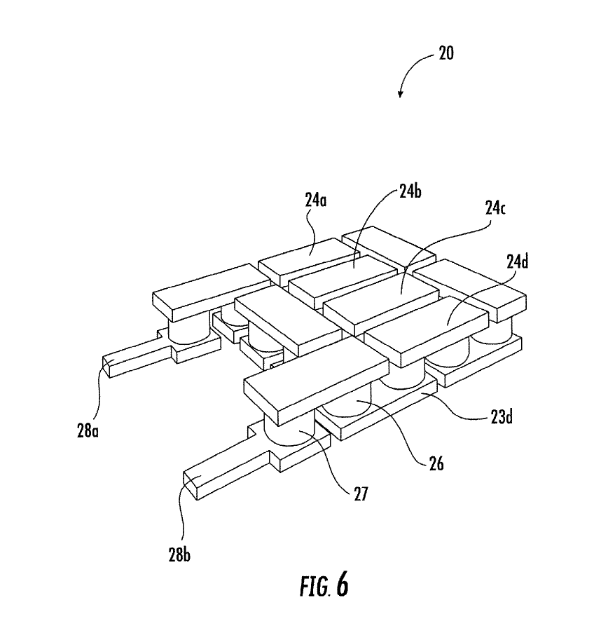

As perhaps best seen in FIG. 3, the thermoelectric generator device 20 illustratively includes first and second terminals 28a-28b coupled to the plurality of bottom contacts 23a-23d. The cumulative generated voltage from the plurality of thermoelectric couples 26a-26d, 27a-27d is provided on the first and second terminals 28a-28b. It should be appreciated that in some active heat sink applications, the first and second terminals 28a-28b would operate as input terminals.

In some embodiments, the semiconductor material polymer matrix may comprise a thermoplastic material. In certain embodiments, the first substrate 22 and the second substrate 21 may each comprise a flexible substrate, such as an organic dielectric (e.g. liquid crystal polymer, polyimide, polyethylene terephthalate Tm 255 C, Tg 78 C, polyethylene naphthalate (PEN) Tm 263 C, Tg 120 C, kapton polyimide Tg ˜350° C.).

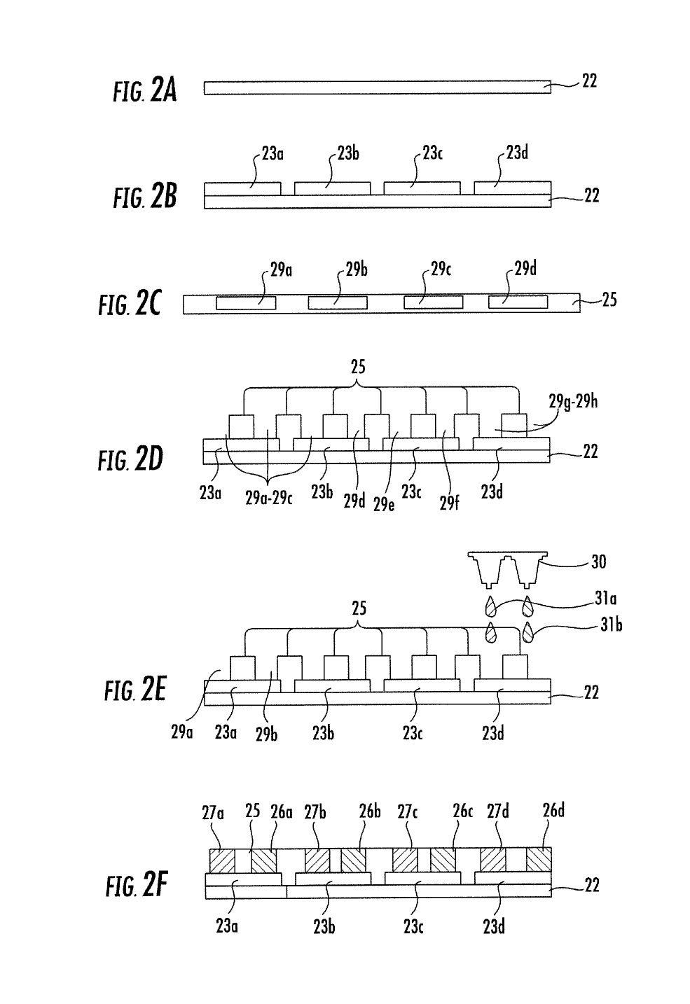

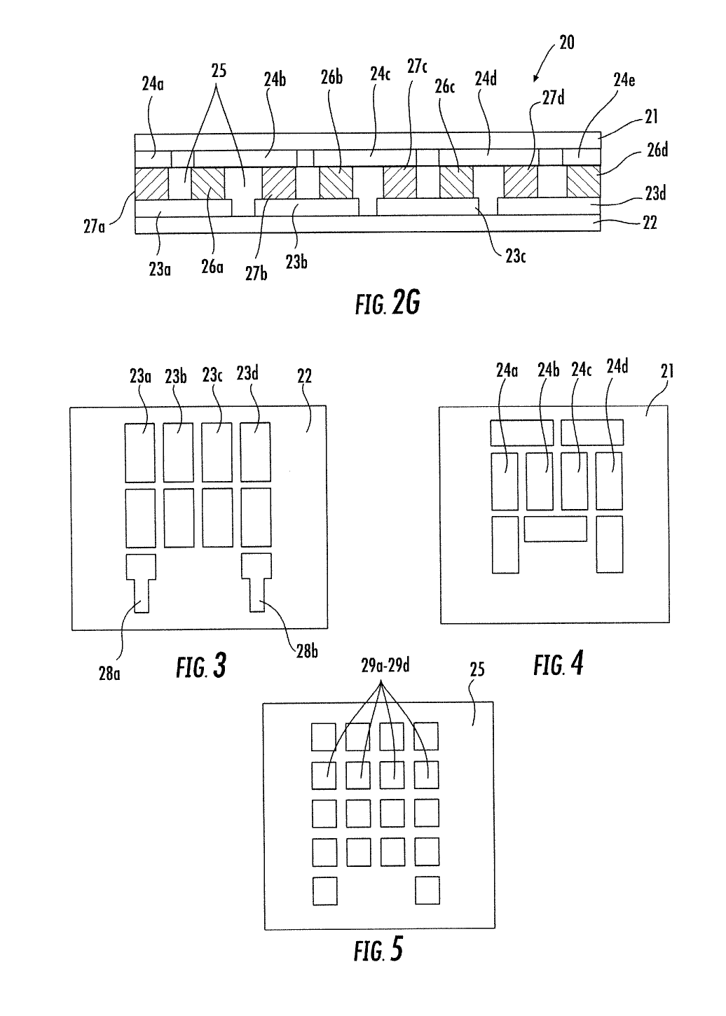

In FIGS. 2A-2B, the method illustratively includes forming a plurality of bottom contacts 23a-23d on a first substrate 22 at Block 13. As perhaps best seen in FIG. 5, the method also includes forming a polymer layer 25 over the first substrate 22 with a plurality of recesses 29a-29h in the polymer layer at Block 14. The plurality of recesses 29a-29h is over the plurality of bottom contacts 23a-23d. In some embodiments, after formation of the polymer layer 25, the method may also include milling (e.g. micro milling) the polymer layer to define the plurality of recesses 29a-29h in the polymer layer. In other embodiments, an etching process (using mask layers) may be used to form the plurality of recesses 29a-29h in the polymer layer 25.

The method illustratively includes forming first and second semiconductor material fluids 31a-31b in the plurality of recesses 29a-29h of the polymer layer 25 to define a plurality of thermoelectric couples 26a-26d, 27a-27d at Block 15. In the illustrated embodiment, the first and second semiconductor material fluids 31a-31b are deposited using an ink-jet printing process from a dual nozzle dispenser 30, and have respective first and second conductivity types (e.g. N-type, P-type conductivity types). Also, the method may include cooling the plurality of thermoelectric couples 26a-26d, 27a-27d to solidify the plurality of thermoelectric couples.

In some embodiments, the method may also include grinding first and second semiconductor materials to generate intermediate first and second semiconductor powders. The first and second semiconductor materials may each comprise appropriately doped Bi₂Te₃, PbTe, CoSb₃, and SiGe, for example. In some embodiments, the grinding process may comprise a ball milling process at the nanoscale (i.e. providing particles on the order of nanometers). In other embodiments, the grinding process may be only to a microscale level.

After generation of the intermediate first and second semiconductor powders, the intermediate first and second semiconductor powders are separately combined in solvent fluid, providing intermediate first and second semiconductor fluids. The intermediate first and second semiconductor fluids are each separately dispersed within a suspension fluid to generate the first and second semiconductor material fluids 31a-31b. In particular, the intermediate first and second semiconductor material fluids respectively represent 6-8% of the first and second semiconductor material fluids (i.e. the suspension fluid makes up the remaining 94-92%). For example, the suspension fluid may comprise a polymer fluid, such as PMMA. In thermoplastic embodiments, the polymer fluid may comprise a heated thermoplastic material. In other words, the intermediate semiconductor fluid is combined with a heated thermoplastic.

The method illustratively includes forming a plurality of top contacts 24a-24e adjacent a second substrate 21. The method further includes positioning the second substrate so that the plurality of top contacts 24a-24e is coupled to the plurality of thermoelectric couples 26a-26d, 27a-27d at Blocks 17-18.

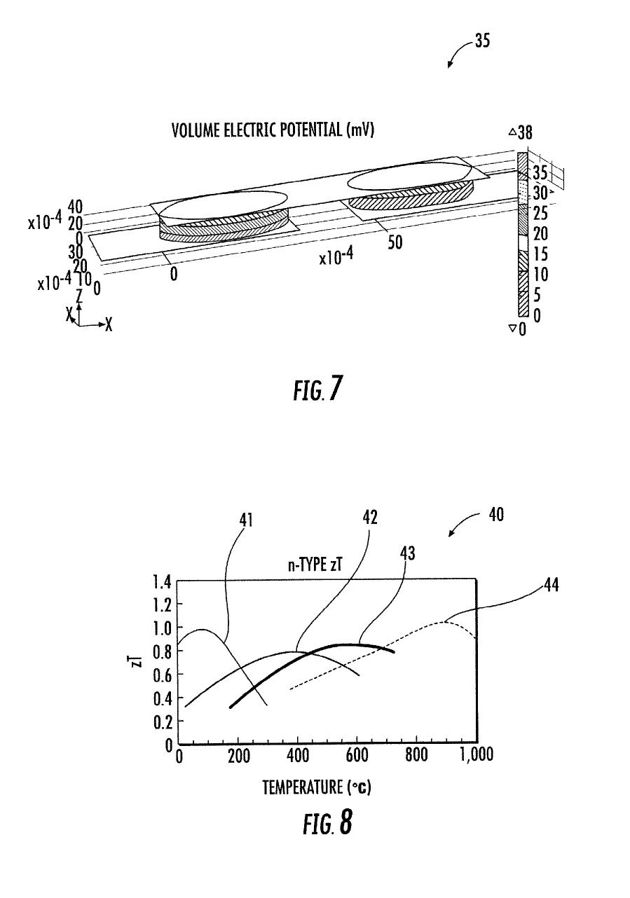

Referring additionally to FIG. 6, each thermoelectric couple 26a-26d, 27a-27d illustratively includes first and second columns of respective first and second conductivity types. In the illustrated embodiment, the columns are cylinder-shaped.

Referring additionally to FIGS. 7-8, a diagram 35 shows electric potential for each thermoelectric couple 26a-26d, 27a-27d in the thermoelectric generator device 20. In particular, diagram 35 is a result of a simulation with the parameters from Table 1. The simulated voltage generated was 38 mV.

TABLE 1

| | Bi₂Te₃ - p | Unit measure | Bi₂Te₃ - n | Unit measure |
|---|---|---|---|---|
| S | 48 | mV/K | 32 | mV/K |
| ρ | 7.5e−6 | Ohm · m | 5e−6 | Ohm · m |
| k | 0.45 | W/Km | 0.54 | W/Km |
| T | 380 | K | 380 | K |
| Z T | 0.26 | | 0.14 | |

Diagram 40 shows thermoelectric efficiency for several materials as temperature varies. Curves 41, 42, 43, 44 respectively represent the semiconductor materials Bi₂Te₃, PbTe, CoSb₃, and SiGe. In some embodiments, the first and second semiconductor fluids may comprise Bi₂Te₃, which operates at peak efficiency of 300 K (i.e. room temperature).

Although not depicted, the method may include forming one or more adhesive/bonding layers for bonding the first and second substrates 22, 21, the polymer layer 25, and the plurality of thermoelectric couples 26a-26d, 27a-27d together. The adhesive/bonding layers may comprise thermally cured adhesive material, which can be deposited by an ink-jet process.

Typical thermoelectric generator devices may suffer from the following issues. Firstly, the typical thermoelectric generator devices may not be applicable to microelectronic devices, and may have low dimension scalability. Secondly, the typical thermoelectric generator devices may have long response times, and have little flexibility (i.e. they are rigid). Also, the typical thermoelectric generator devices may be manufactured using typical bulk semiconductor materials. Indeed, in typical manufacturing processes, planar films are used in assembly.

The thermoelectric generator device 20 may provide an approach to the problems/issues of typical thermoelectric generator devices. Advantageously, the thermoelectric generator device 20 may use low cost materials and manufacturing techniques compatible with the processes of printed electronics, which reduces cost and eases manufacture. Moreover, the disclosed manufacturing technique allows for a scalable design on flexible organic substrates. Also, since the plurality of thermoelectric couples 26a-26d, 27a-27d is formed from nanoscale powder, the thermoelectric efficiency of the thermoelectric generator device 20 is improved since nanomaterials have intrinsic beneficial properties. In particular, these beneficial properties are not found in bulk materials and make them good thermoelectric materials.

For example, one of these beneficial properties is a reduction in thermal lattice conductivity XL. In particular, the use of nanomaterials provides an approach to improving thermoelectric efficiency by overcoming the typical interdependence of base parameters that affect the efficiency. Also, the thermoelectric generator device 20 provides a miniaturized footprint and a light weight device, thereby suiting mobile applications.

Further, in recent years, studies of superlattices, semi-empirical models, and numerical simulations have shown that in order to benefit from nanostructures regarding thermoelectric properties (i.e. by lowering the thermal conductivity), it is not required that interfaces be atomically perfect or have exact geometries. Rather it is sufficient to have high density interfaces without the need to have special geometry or structure, significantly simplifying the manufacturing processes and thus allowing production of the material in large quantities. Nanocomposites are materials that fit this description; using thermoelectric materials, this increases the electrical conductivity and decreases the heat, resulting in a net growth figure of merit ZT.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

That which is claimed is:

1. A method for making a thermoelectric generator device, the method comprising:
forming a plurality of bottom contacts on a first substrate;
forming a polymer layer over the first substrate with a plurality of recesses therein, the plurality of recesses being over the plurality of bottom contacts;
forming at least one semiconductor material fluid in the plurality of recesses of the polymer layer to define a plurality of thermoelectric couples coupled to the plurality of bottom contacts; and
forming a plurality of top contacts adjacent a second substrate, and positioning the second substrate so that the plurality of top contacts is coupled to the plurality of thermoelectric couples.

2. The method of claim 1 further comprising:
grinding semiconductor material to generate semiconductor powder; and
combining the semiconductor powder with a suspension fluid and a solvent to generate the at least one semiconductor material fluid.

3. The method of claim 2 wherein the suspension fluid comprises a polymer fluid.

4. The method of claim 3 wherein the polymer fluid comprises a heated thermoplastic material.

5. The method of claim 1 wherein forming the at least one semiconductor material fluid comprises ink-jet printing the at least one semiconductor material fluid.

6. The method of claim 1 further comprising milling the polymer layer to define the plurality of recesses therein.

7. The method of claim 1 wherein the first substrate and the second substrate, and the polymer layer each comprises a flexible layer.

8. The method of claim 1 wherein the at least one semiconductor material fluid comprises first and second semiconductor material fluids having respective first and second conductivity types.

9. The method of claim 1 further comprising cooling the plurality of thermoelectric couples to solidify the plurality of thermoelectric couples.

10. A method for making a thermoelectric generator device, the method comprising:
forming a plurality of bottom contacts on a first substrate;
forming a polymer layer over the first substrate with a plurality of recesses therein, the plurality of recesses being over the plurality of bottom contacts;
ink-jet printing first and second semiconductor material fluids having respective first and second conductivity types in the plurality of recesses of the polymer layer to define a plurality of thermoelectric couples coupled to the plurality of bottom contacts; and
forming a plurality of top contacts adjacent a second substrate, and positioning the second substrate so that the plurality of top contacts is coupled to the plurality of thermoelectric couples.

11. The method of claim 10 further comprising:
grinding semiconductor material to generate semiconductor powder; and
combining the semiconductor powder with a suspension fluid and a solvent to generate the first and second semiconductor material fluids.

12. The method of claim 11 wherein the suspension fluid comprises a polymer fluid.

13. The method of claim 12 wherein the polymer fluid comprises a heated thermoplastic material.

14. The method of claim 10 further comprising milling the polymer layer to define the plurality of recesses therein.

15. The method of claim 10 wherein the first substrate and the second substrate, and the polymer layer each comprises a flexible layer.

16. A thermoelectric generator device comprising:
a first substrate;
a plurality of bottom contacts carried by said first substrate;
a polymer layer over said first substrate and said plurality of bottom contacts, and defining a plurality recesses therein;
a semiconductor material polymer matrix filling the plurality of recesses in said polymer layer and defining a plurality of thermoelectric couples;
a plurality of top contacts coupled to said plurality of thermoelectric couples; and
a second substrate carrying said plurality of top contacts.

17. The thermoelectric generator device of claim 16 wherein each thermoelectric couple comprises first and second columns of respective first and second conductivity types.

18. The thermoelectric generator device of claim 16 further comprises first and second terminals coupled to said plurality of bottom contacts.

19. The thermoelectric generator device of claim 16 wherein the semiconductor material polymer matrix comprises a thermoplastic material polymer matrix.

20. The thermoelectric generator device of claim 16 wherein said first substrate and said second substrate, and said polymer layer each comprises a flexible layer.
